(19) United States
(12) Patent Application Publication
(10) Pub. No.: US 2011/0297213 A1
(43) Pub. Date: Dec. 8, 2011

(54) Triple Junction Solar Cell

(76) Inventor: Michael Hideto Tsutagawa, Sand City, CA (US)

(21) Appl. No.: 12/686,266

(22) Filed: Jan. 12, 2010

Related U.S. Application Data
(60) Provisional application No. 61/144,398, filed on Jan. 13, 2009.

(51) Int. Cl. H01L 31/0352; H01L 31/18

(52) U.S. Cl. 136/255; 438/87; 438/94; 257/E31.037; 257/E31.054

(57) ABSTRACT

An energy efficient triple junction InGaP/GaAs/Ge solar cell. In one embodiment, the triple junction InGaP/GaAs/Ge solar cell includes: a bottom Ge layer; a first tunnel junction layer above the bottom Ge layer; a middle GaAs layer above the first tunnel junction layer; a second tunnel junction layer above the middle GaAs layer; and a top InGaP layer above the second tunnel junction layer.

### CROSS-REFERENCE TO RELATED APPLICATIONS

This application claims the benefit of U.S. Provisional Application No. 61/144,398, filed Jan. 13, 2009, which is hereby incorporated in its entirety by reference.

### BACKGROUND OF THE INVENTION

1. Field of the Invention

The present invention relates generally to solar cells. More particularly, the invention relates to a triple junction solar cell.

2. Description of the Related Art

Solar energy is an important alternative energy source to fossil fuels. Solar cells are used to collect solar energy and covert the solar energy to electrical energy. Increasing the efficiency of solar cells results in more deliverable electrical energy.

### SUMMARY OF THE INVENTION

In accordance with one embodiment, a triple junction InGaP/GaAs/Ge solar cell includes: a bottom Ge layer; a first tunnel junction layer above the bottom Ge layer; a middle GaAs layer above the first tunnel junction layer; a second tunnel junction layer above the middle GaAs layer; and a top InGaP layer above the second tunnel junction layer. In one embodiment, light, such as sunlight, enters the triple junction solar cell through the top InGaP layer and energy is produced by the triple junction solar cell. In one embodiment, the bottom Ge layer includes electrically conductive contacts that permit energy produced by the triple junction solar cell to be conducted to other devices, for example, energy storage devices and/or loads.

In accordance with another embodiment, a method for forming a triple junction InGaP/GaAs/Ge solar cell includes: forming a bottom Ge layer; forming a first tunnel junction layer in contact with the bottom Ge layer; forming a middle GaAs layer in contact with the first tunnel junction layer; forming a second tunnel junction layer in contact with the middle GaAs layer; and, forming a top InGaP layer in contact with the second tunnel junction layer.

Embodiments in accordance with the invention are best understood by reference to the following detailed description when read in conjunction with the accompanying drawings.

### BRIEF DESCRIPTION OF THE DRAWINGS

FIG. 1 is a cross sectional diagram of a triple junction InGaP/GaAs/Ge solar cell in accordance with one embodiment.

FIG. 2 is a diagram generally illustrating spectral separation in the triple junction solar cell of FIG. 1 in accordance with one embodiment.

FIG. 3 is a table of the simulated cell performance parameters of the triple junction solar cell of FIG. 1 in accordance with one embodiment.

FIG. 4 is a simulated I-V curve of the triple junction solar cell of FIG. 1 in accordance with one embodiment.

FIGS. 5A and 5B illustrate a process flow diagram of a method for fabricating the triple junction solar cell of FIG. 1 in accordance with one embodiment.

Embodiments in accordance with the invention are further described herein with reference to the drawings.

### DETAILED DESCRIPTION OF THE INVENTION

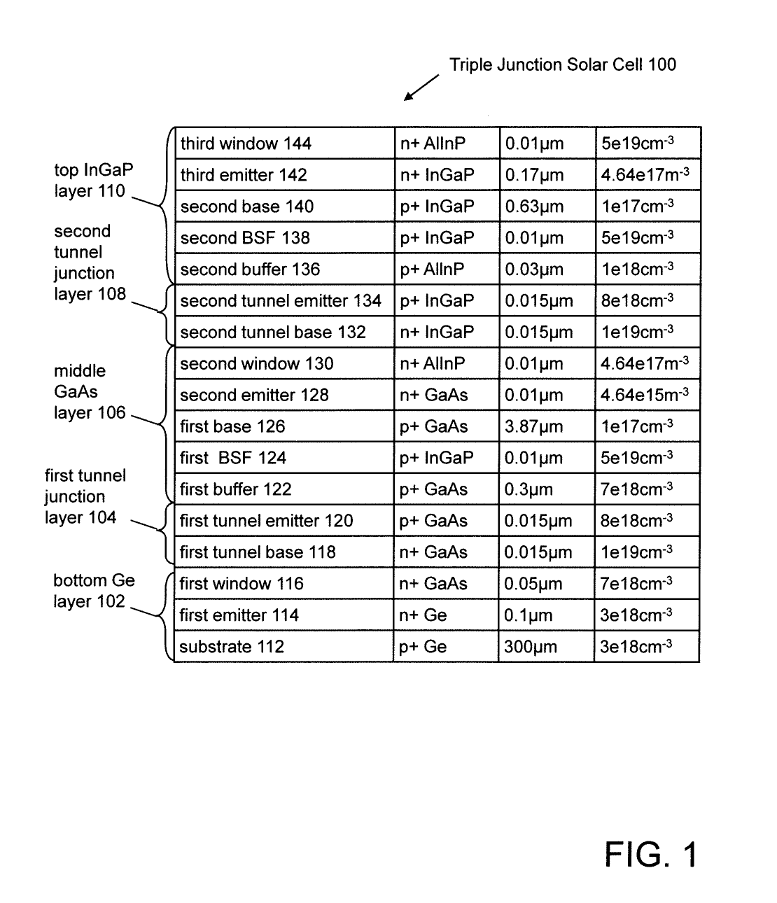

FIG. 1 is a cross sectional diagram of a triple junction InGaP/GaAs/Ge solar cell 100 in accordance with one embodiment. In one embodiment, triple junction InGaP/GaAs/Ge (indium gallium phosphide/gallium arsenide/germanium) solar cell 100 includes: a bottom Ge (germanium) layer 102; a first tunnel junction layer 104 above the bottom Ge layer 102; a middle GaAs (gallium/arsenide) layer 106 above the first tunnel junction layer 104; a second tunnel junction layer 108 above the middle GaAs layer 106; and a top InGaP (indium gallium phosphide) layer 110 above the second tunnel junction layer 108.

As illustrated in FIG. 1, in one embodiment, bottom Ge layer 102 is formed of 3 sub-layers: a substrate layer 112; a first emitter layer 114 above substrate layer 112; and, a first window layer 116 above first emitter layer 114. More particularly, in one embodiment, substrate layer 112 is a p+ doped Ge layer at or about 300 μm (microns) thickness with a p+ doping level concentration at or about 3e18 cm⁻³; first emitter layer 114 is an n+ doped Ge layer at or about 0.1 μm (microns) thickness with an n+ doping level concentration at or about 3e18 cm⁻³; and, first window layer 116 is an n+ doped GaAs layer at or about 0.05 μm thickness with an n+ doping level concentration at or about 7e18 cm⁻³.

In one embodiment, first tunnel junction layer 104 is formed of 2 sub-layers: a first tunnel base layer 118 above first window layer 116; and, a first tunnel emitter layer 120 above first tunnel base layer 118. More particularly, in one embodiment, first tunnel base layer 118 is an n+ doped GaAs layer at or about 0.015 μm (microns) thickness with an n+ doping level concentration at or about 1e19 cm⁻³; and, first tunnel emitter layer 120 is a p+ doped GaAs layer at or about 0.015 μm (microns) thickness with a p+doping level concentration at or about 8e18 cm⁻³.

In one embodiment, middle GaAs layer 106 is formed of 5 sub-layers: a first buffer layer 122 above first tunnel emitter layer 120; a first BSF (back surface field) layer 124 above first buffer layer 122; a first base layer 126 above first BSF layer 124; a second emitter layer 128 above first base layer 126; and, a second window layer 130 above second emitter layer 128. More particularly, in one embodiment, first buffer layer 122 is a p+ doped GaAs layer at or about 0.3 μm (microns) thickness with a p+ doping level concentration at or about 7e18 cm⁻³; first BSF layer 124 is a p+ doped InGaP layer at or about 0.01 μm (microns) thickness with a p+ doping level concentration at or about 5e19 cm⁻³; first base layer 126 is a p+ doped GaAs layer at or about 3.87 μm (microns) thickness with a p+ doping level concentration at or about 1e17 cm⁻³; second emitter layer 128 is an n+ doped GaAs layer at or about 0.01 μm (microns) thickness with an n+ doping level concentration at or about 4.64e15 cm⁻³; and, second window layer 130 is an n+ doped AlInP (aluminum indium phosphide) layer at or about 0.01 μm thickness with an n+ doping level concentration at or about 4.64e17 cm⁻³.

In one embodiment, second tunnel junction layer 108 is formed of 2 sub-layers: a second tunnel base layer 132 above second window layer 130; and, a second tunnel emitter layer 134 above second tunnel base layer 132. More particularly, in one embodiment, second tunnel base layer 132 is an n+ doped InGaP layer at or about 0.015 μm (microns) thickness with an n+ doping level concentration at or about 1e19 cm⁻³; and, second tunnel emitter layer 134 is a p+ doped InGaP layer at or about 0.015 μm (microns) thickness with a p+ doping level concentration at or about 8e18 cm⁻³.

In one embodiment, top InGaP layer 110 is formed of 5 sub-layers: a second buffer layer 136 above second tunnel emitter layer 134; a second BSF (back surface field) layer 138 above second buffer layer 136; a second base layer 140 above second BSF layer 138; a third emitter layer 142 above second base layer 140; and, a third window layer 144 above third emitter layer 142. More particularly, in one embodiment, second buffer layer 136 is a p+ doped AlInP layer at or about 0.03 μm (microns) thickness with a p+ doping level concentration at or about 1e18 cm⁻³; second BSF layer 138 is a p+ doped InGaP layer at or about 0.01 μm (microns) thickness with a p+ doping level concentration at or about 5e19 cm⁻³; second base layer 140 is a p+ doped InGaP layer at or about 0.63 μm (microns) thickness with a p+ doping level concentration at or about 1e17 cm⁻³; third emitter layer 142 is an n+ doped InGaP layer at or about 0.17 μm (microns) thickness with an n+ doping level concentration at or about 4.64e17 cm⁻³; and third window layer 144 is an n+ doped AlInP layer at or about 0.01 μm thickness with an n+ doping level concentration at or about 5e19 cm⁻³.

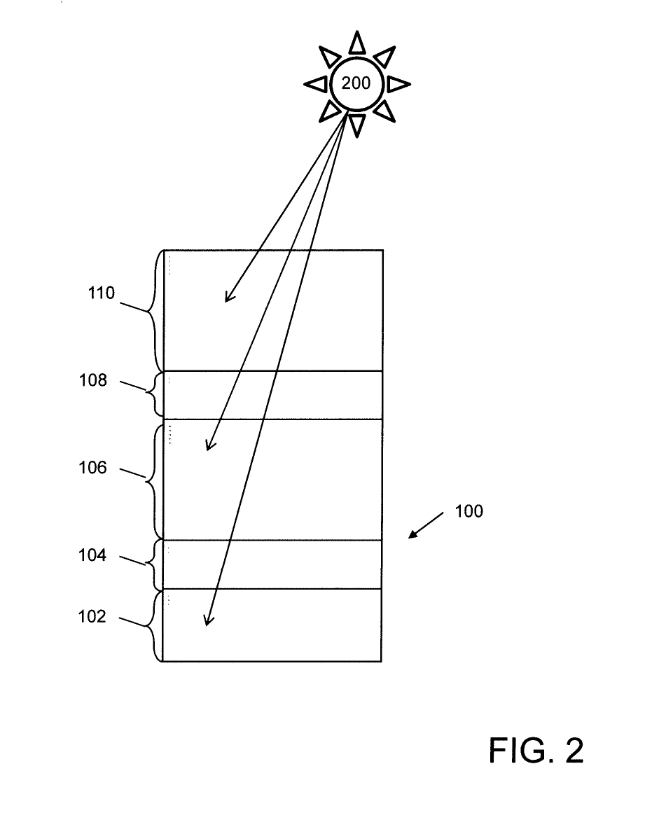

In one embodiment, triple junction solar cell 100 is formed as a tandem cell. For a given solar spectrum, triple junction solar cell 100 attempts to take advantage of the spectral response of each layer's band gaps. FIG. 2 is a diagram generally illustrating spectral separation in triple junction solar cell 100 in accordance with one embodiment.

Referring now to FIGS. 1 and 2 together, in one embodiment, top InGaP layer 110 is formed as the top cell layer to absorb higher-energy photons from a light source 200 and allows the lower-energy photons to pass through to the underlying layers of triple junction solar cell 100. In one embodiment, light source 200 is a light source of AM0 intensity (0.1353 Watts/cm²). Middle GaAs layer 106 is formed as the middle cell to absorb mid-energy photons and allows the lower energy photons to pass through to the underlying layers of triple junction solar cell 100. Bottom Ge layer 102 is formed as the bottom cell and absorbs remaining energy photons for power generation. In one embodiment, electrically conductive contacts (not shown) can be attached to triple junction solar cell 100 to allow energy produced by triple junction solar cell 100 to be transferred to other devices, such as energy storage devices or loads.

As illustrated in FIGS. 1 and 2, triple junction solar cell 100 is a stacked configuration in which the layer that produces the least current is placed on top (nearest the light source). Shadowing effects of an upper layer affects performance of the layers below. In optimizing the design of triple junction solar cell 100, each layer is designed so that the overall cell produces at or about maximum power output by varying doping concentrations and thicknesses.

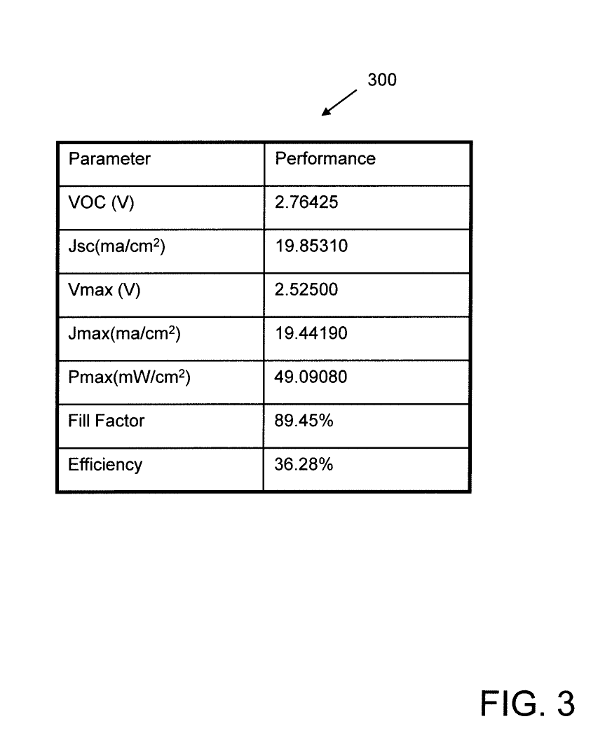

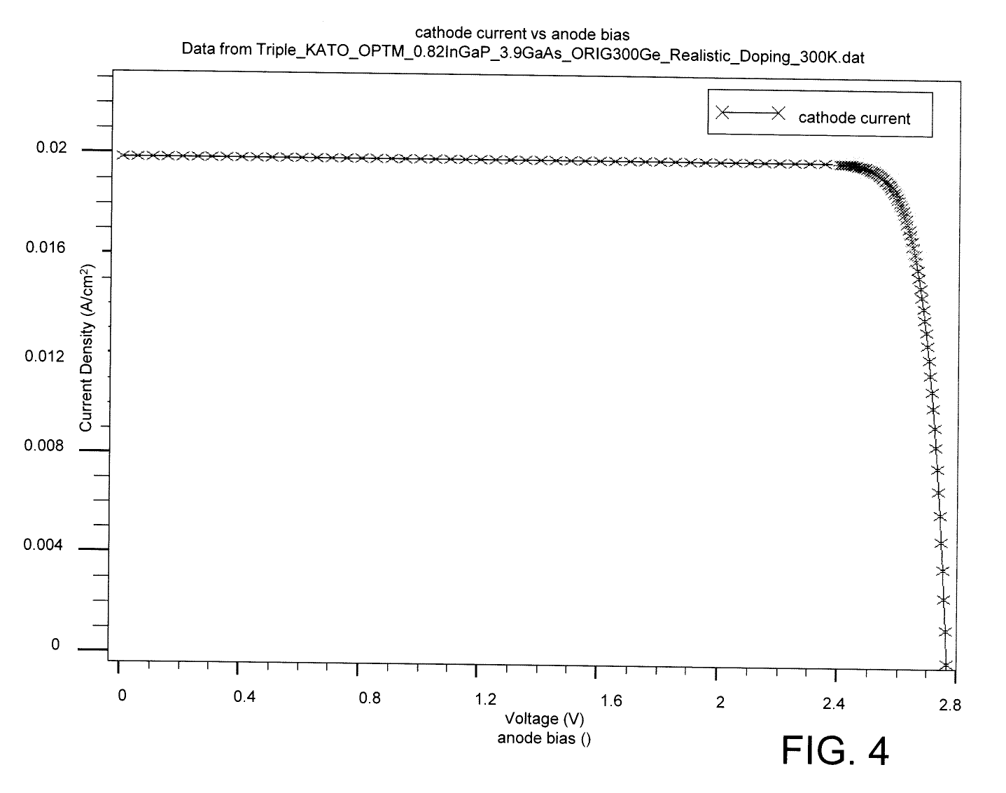

FIG. 3 is a table of the simulated cell performance parameters of triple junction solar cell 100 in accordance with one embodiment. FIG. 4 is a simulated I-V curve of triple junction solar cell 100 in accordance with one embodiment. Performance simulation of triple junction solar cell 100 was performed using the Silvaco ATLAS device simulation framework as a virtual wafer fabrication tool (Silvaco ATLAS is available from Silvaco Data Systems Inc., Santa Clara, Calif.).

Referring now to FIGS. 1, 3 and 4, for a specific top layer thickness (i.e., the top InGaP layer 110), the middle layer (i.e., the middle GaAs layer 106) was thickened proportionately in order to “match” the maximum current produced by the top layer. The current matching point and maximum efficiency point relationships were obtained at top InGaP layer 110 thicknesses of about 0.75 μm-0.82 μm. The maximum efficiency triple junction solar cell 100 design was obtained with an InGaP layer 110 thickness of 0.82 μm, a GaAs layer 106 thickness of 3.9 μm, and a Ge layer 102 thickness cell of 300.15 μm under AM0 light intensity to produce an efficiency of approximately 36.28% and occurred about 1.2 μm from the current matching point. InGaP thicknesses greater than 0.83 μm showed decreasing efficiency and an increasing efficiency point of about 1.3 μm from the current matching point.

Due to its high current density, bottom Ge layer 102 was expected to be current limited by the InGaP/GaAs layers above it. However, simulations showed that once an increased specific thickness of the InGaP/GaAs layers was reached, eventual current choking of bottom Ge layer 102 occurred due to the shadowing effects of the upper layers. The occurrence of current choking indicated an optimal performance point for triple junction solar cell 100 was achieved with an overall efficiency of 36.28%.

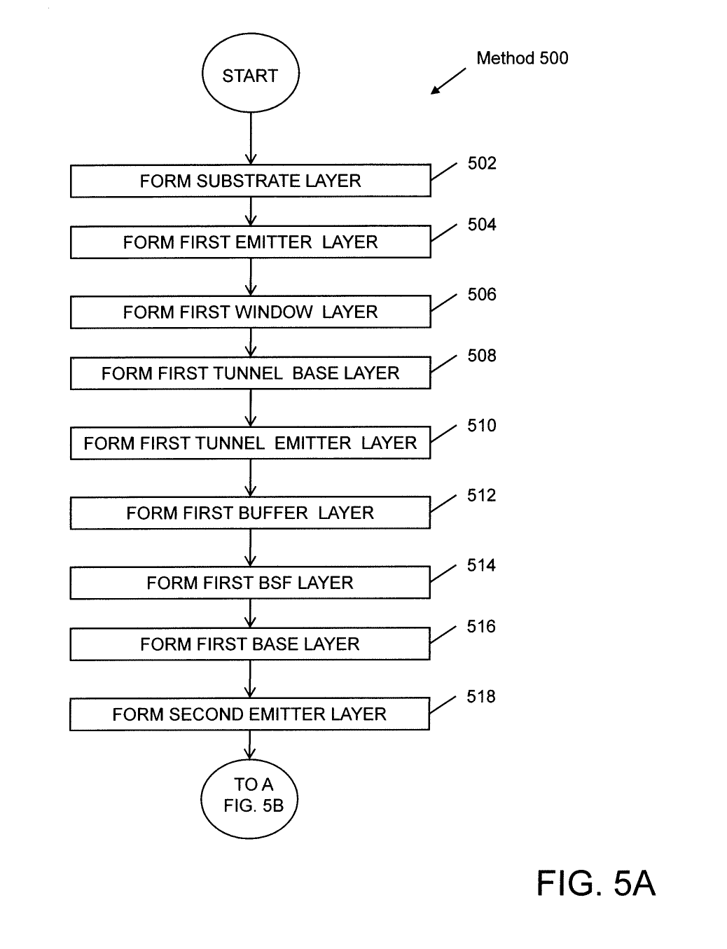

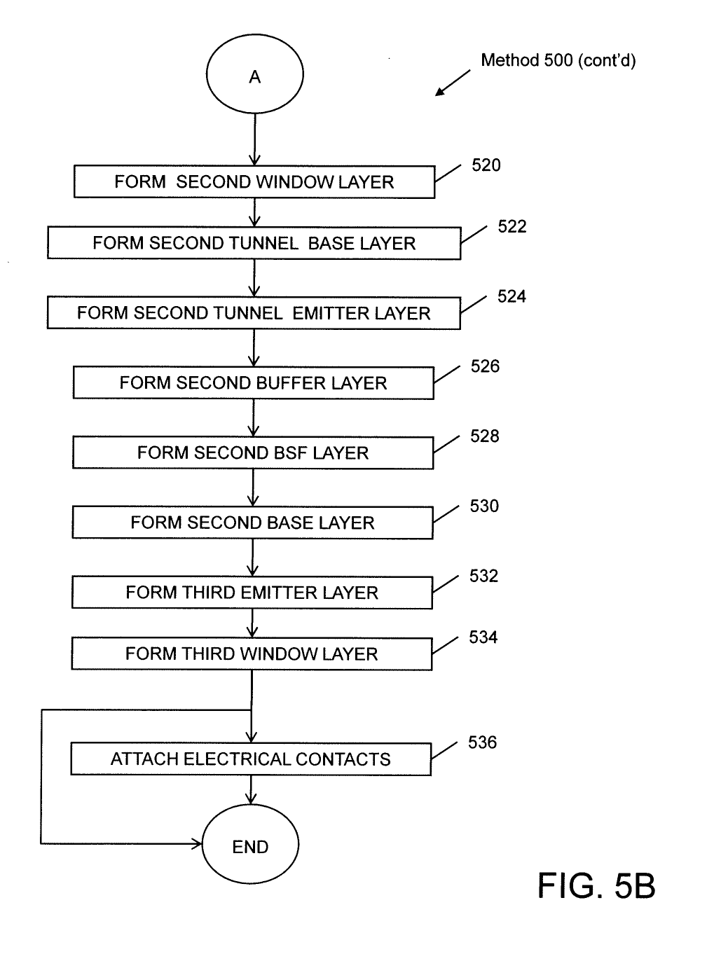

FIGS. 5A and 5B illustrate a process flow diagram of a method 500 for fabricating the triple junction solar cell 100 in accordance with one embodiment. Referring generally to FIGS. 5A and 5B, in method 500: formation of bottom Ge layer 102 is described with reference to operations 502 through 506; formation of first tunnel junction layer 104 is described with reference to operations 508 through 510; formation of middle GaAs layer 106 is described with reference to operations 512 through 520; formation of second tunnel junction layer 108 is described with reference to operations 522 through 524; and, formation of top InGaP layer 110 is described with reference to operations 526 through 534. Optionally, electrical contacts can be formed or otherwise attached to triple junction solar cell 100 in operation 536 to permit transfer of energy generated by triple junction solar cell 100 to other devices.

Referring now initially to FIG. 5A, in one embodiment, method 500 is entered at a FORM SUBSTRATE LAYER operation 502. In FORM SUBSTRATE LAYER operation 502, substrate layer 112 is formed by a fabrication technique such as deposition. In one embodiment, substrate layer 112 is a p+ doped Ge layer of about 300 μm (microns) thickness with a p+ doping level concentration of 3e18 cm⁻³. From FORM SUBSTRATE LAYER operation 502, processing moves to a FORM FIRST EMITTER LAYER operation 504.

In FORM FIRST EMITTER LAYER operation 504, first emitter layer 114 is formed above substrate layer 112. In one embodiment, first emitter layer 114 is formed by a fabrication technique such as deposition. In one embodiment, first emitter layer 114 is an n+ doped Ge layer at or about 0.1 μm (microns) thickness with an n+ doping level concentration at or about 3e18 cm⁻³. From FORM FIRST EMITTER LAYER operation 504, processing moves to a FORM FIRST WINDOW LAYER operation 506.

In FORM FIRST WINDOW LAYER operation 506, first window layer 116 is formed above first emitter layer 114. In one embodiment, first window layer 116 is formed by a fabrication technique such as deposition. In one embodiment, first window layer 116 is an n+ doped GaAs layer at or about 0.05 μm with an n+ doping level concentration at or about 7e18 cm⁻³. From FORM FIRST WINDOW LAYER operation 506, processing moves to a FORM FIRST TUNNEL BASE LAYER operation 508.

In FORM FIRST TUNNEL BASE LAYER operation 508, first tunnel base layer 118 is formed above first window layer 116. In one embodiment, first tunnel base layer 118 is formed by a fabrication technique such as deposition. In one embodiment, first tunnel base layer 118 is an n+ doped GaAs layer at or about 0.015 μm (microns) thickness with an n+ doping level concentration at or about 1e19 cm⁻³. From FORM FIRST TUNNEL BASE LAYER operation 508, processing moves to a FORM FIRST TUNNEL EMITTER LAYER operation 510.

In FORM FIRST TUNNEL EMITTER LAYER operation 510, first tunnel emitter layer 120 is formed above first tunnel base layer 118. In one embodiment, first tunnel emitter layer 120 is formed by a fabrication technique such as deposition. In one embodiment, first tunnel emitter layer 120 is a p+ doped GaAs layer at or about 0.015 μm (microns) thickness with a p+ doping level concentration at or about 8e18 cm⁻³. From FORM FIRST TUNNEL EMITTER LAYER operation 510 processing moves to a FORM FIRST BUFFER LAYER operation 512.

In FORM FIRST BUFFER LAYER operation 512, first buffer layer 122 is formed above first tunnel emitter layer 120. In one embodiment, first buffer layer 122 is formed by a fabrication technique such as deposition. In one embodiment, first buffer layer 122 is a p+ doped GaAs layer at or about 0.3 μm (microns) thickness with a p+ doping level concentration at or about 7e18 cm⁻³. From FORM FIRST BUFFER LAYER operation 512 processing moves to a FORM FIRST BSF LAYER operation 514.

In FORM FIRST BSF LAYER operation 514, first BSF layer 124 is formed above first buffer layer 122. In one embodiment, first BSF layer 124 is formed by a fabrication technique such as deposition. In one embodiment, first BSF layer 124 is a p+ doped InGaP layer at or about 0.01 μm (microns) thickness with a p+ doping level concentration at or about 5e19 cm⁻³. From FORM FIRST BSF LAYER operation 514 processing moves to a FORM FIRST BASE LAYER operation 516.

In FORM FIRST BASE LAYER operation 516, first base layer 126 is formed above first BSF layer 124. In one embodiment, first base layer 126 is formed by a fabrication technique such as deposition. In one embodiment, first base layer 126 is a p+ doped GaAs layer at or about 3.87 μm (microns) thickness with a p+ doping level concentration at or about 1e17 cm⁻³. From FORM FIRST BASE LAYER operation 516 processing moves to a FORM SECOND EMITTER LAYER operation 518.

In FORM SECOND EMITTER LAYER operation 518, second emitter layer 128 is formed above first base layer 126. In one embodiment, second emitter layer 128 is formed by a fabrication technique such as deposition. In one embodiment, second emitter layer 128 is an n+ doped GaAs layer at or about 0.01 μm (microns) thickness with an n+ doping level concentration at or about 4.64e15 cm⁻³. From FORM SECOND EMITTER LAYER operation 518 processing moves to a FORM SECOND WINDOW LAYER operation 520.

Referring now to FIG. 5B, in FORM SECOND WINDOW LAYER operation 520, second window layer 130 is formed above second emitter layer 128. In one embodiment, second window layer 130 is formed by a fabrication technique such as deposition. In one embodiment, second window layer 130 is an n+ doped AlInP (aluminum indium phosphide) layer at or about 0.01 μm thickness with an n+ doping level concentration at or about 4.64e17 cm⁻³. From FORM SECOND WINDOW LAYER operation 520 processing moves to FORM SECOND TUNNEL BASE LAYER operation 522.

In FORM SECOND TUNNEL BASE LAYER operation 522, second tunnel base layer 132 is formed above second window layer 130. In one embodiment, second tunnel base layer 132 is formed by a fabrication technique such as deposition. In one embodiment, second tunnel base layer 132 is an n+ doped InGaP layer at or about 0.015 μm (microns) thickness with an n+ doping level concentration at or about 1e19 cm⁻³. From FORM SECOND TUNNEL BASE LAYER operation 522 processing moves to a FORM SECOND TUNNEL EMITTER LAYER operation 524.

In FORM SECOND TUNNEL EMITTER LAYER operation 524, second tunnel emitter layer 134 is formed above second tunnel base layer 132. In one embodiment, second tunnel emitter layer 134 is formed by a fabrication technique such as deposition. In one embodiment, second tunnel emitter layer 134 is a p+ doped InGaP layer at or about 0.015 μm (microns) thickness with a p+ doping level concentration at or about 8e18 cm⁻³. From FORM SECOND TUNNEL EMITTER LAYER operation 524 processing moves to a FORM SECOND BUFFER LAYER operation 526.

In FORM SECOND BUFFER LAYER operation 526, second buffer layer 136 is formed above second tunnel emitter layer 134. In one embodiment, second buffer layer 136 is formed by a fabrication technique such as deposition. In one embodiment, second buffer layer 136 is a p+ doped AlInP layer at or about 0.03 μm (microns) thickness with a p+ doping level concentration at or about 1e18 cm⁻³. From FORM SECOND BUFFER LAYER operation 526 processing moves to a FORM SECOND BSF LAYER operation 528.

In FORM SECOND BSF LAYER operation 528, second BSF layer 138 is formed above second buffer layer 136. In one embodiment, second BSF layer 138 is formed by a fabrication technique such as deposition. In one embodiment, second BSF layer 138 is a p+ doped InGaP layer at or about 0.01 μm (microns) thickness with a p+ doping level concentration at or about 5e19 cm⁻³. From FORM SECOND BSF LAYER operation 528 processing moves to a FORM SECOND BASE LAYER operation 530.

In FORM SECOND BASE LAYER operation 530, second base layer 140 is formed above second BSF layer 138. In one embodiment, second base layer 140 is formed by a fabrication technique such as deposition. In one embodiment, second base layer 140 is a p+ doped InGaP layer at or about 0.63 μm (microns) thickness with a p+ doping level concentration at or about 1e17 cm⁻³. From FORM SECOND BASE LAYER operation 530 processing moves to a FORM THIRD EMITTER LAYER operation 532.

In FORM THIRD EMITTER LAYER operation 532, third emitter layer 142 is formed above second base layer 140. In one embodiment, third emitter layer 142 is formed by a fabrication technique such as deposition. In one embodiment, third emitter layer 142 is an n+ doped InGaP layer at or about 0.17 μm (microns) thickness with an n+ doping level concentration at or about 4.64e17 cm⁻³. From FORM THIRD EMITTER LAYER operation 532 processing moves to a FORM THIRD WINDOW LAYER operation 534.

In FORM THIRD WINDOW LAYER operation 534, third window layer 144 is formed above third emitter layer 142. In one embodiment, third window layer 144 is formed by a fabrication technique such as deposition. In one embodiment, third window layer 144 is an n+ doped AlInP layer at or about 0.01 μm thickness with an n+ doping level concentration at or about 5e19 cm⁻³. From FORM THIRD WINDOW LAYER operation 534, processing exits method 500 or optionally moves to optional ADD ELECTRICAL CONTACTS operation 536.

In optional ADD ELECTRICAL CONTACTS operation 536, electrically conductive contacts (herein termed electrical contacts) are formed on or attached to resultant triple junction solar cell 100 to allow energy generated by triple junction solar cell 100 to be transferred to other devices, such as energy storage devices or loads. From optional ADD ELECTRICAL CONTACTS operation 536, processing exits method 500.

It can be understood by those of skill in the art the above method 500 is adaptable for use in large scale fabrication in which large wafers are manufactured and then sub-divided into smaller individual solar cells.

This disclosure provides exemplary embodiments of the present invention. The scope of the present invention is not limited by these exemplary embodiments. Numerous variations, whether explicitly provided for by the specification or implied by the specification or not, may be implemented by one of skill in the art in view of this disclosure.

What is claimed is:

1. A triple junction solar cell comprising:
a bottom Ge layer;
a first tunnel junction layer in contact with said bottom Ge layer;
a middle GaAs layer in contact with said first tunnel junction layer;
a second tunnel junction layer in contact with said middle GaAs layer; and
a top InGaP layer in contact with said second tunnel junction layer.

2. The triple junction solar cell of claim 1 wherein said bottom Ge layer comprises:
a substrate layer of p+ Ge;
a first emitter layer of n+ Ge; and
a first window layer of n+ GaAs.

3. The triple junction solar cell of claim 1 wherein said first tunnel junction layer comprises:
a first tunnel base layer of n+ GaAs; and
a first tunnel emitter layer of p+ GaAs.

4. The triple junction solar cell of claim 1 wherein said middle GaAs layer comprises:
a first buffer layer of p+ GaAs;
a first BSF layer of p+ InGaP;
a first base layer of p+ GaAs;
a second emitter layer of n+ GaAs; and
a second window layer of n+ AlInP.

5. The triple junction solar cell of claim 1 wherein said second tunnel junction layer comprises:
a second tunnel base layer of n+ InGaP; and
a second tunnel emitter layer of p+ InGaP.

6. The triple junction solar cell of claim 1 wherein said top InGaP layer comprises:
a second buffer layer of p+ AlInP;
a second BSF layer of p+ InGaP;
a second base layer of p+ InGaP;
a third emitter layer of n+ InGaP; and
a third window layer of n+ AlInP.

7. The triple junction solar cell of claim 1 wherein said bottom Ge layer comprises:
a substrate layer of doped p+ Ge of thickness at or about 300 μm;
a first emitter layer of n+ Ge of thickness at or about 0.1 μm; and
a first window layer of n+ GaAs of thickness at or about 0.05 μm.

8. The triple junction solar cell of claim 1 wherein said first tunnel junction layer comprises:
a first tunnel base layer of n+ GaAs of thickness at or about 0.015 μm; and
a first tunnel emitter layer of p+ GaAs of thickness at or about 0.015 μm.

9. The triple junction solar cell of claim 1 wherein said middle GaAs layer comprises:
a first buffer layer of p+ GaAs of thickness at or about 0.3 μm;
a first BSF layer of p+ InGaP of thickness at or about 0.01 μm;
a first base layer of p+ GaAs of thickness at or about 3.87 μm;
a second emitter layer of n+ GaAs of thickness at or about 0.01 μm; and
a second window layer of n+ AlInP of thickness at or about 0.01 μm.

10. The triple junction solar cell of claim 1 wherein said second tunnel junction layer comprises:
a second tunnel base layer of n+ InGaP of thickness 0.015 μm; and
a second tunnel emitter layer of p+ InGaP of thickness 0.015 μm.

11. The triple junction solar cell of claim 1 wherein said top InGaP layer comprises:
a second buffer layer of p+ AlInP of thickness at or about 0.03 μm;
a second BSF layer of p+ InGaP of thickness at or about 0.01 μm;
a second base layer of p+ InGaP of thickness at or about 0.63 μm;
a third emitter layer of n+ InGaP of thickness at or about 0.17 μm; and
a third window layer of n+ AlInP of thickness at or about 0.01 μm.

12. The triple junction solar cell of claim 1 wherein said bottom Ge layer comprises:
a substrate layer of doped p+ Ge of thickness at or about 300 μm with a p+ doping concentration level at or about 3e18 cm⁻³;
a first emitter layer of n+ Ge of thickness at or about 0.1 μm with an n+ doping concentration level at or about 3e18 cm⁻³; and
a first window layer of n+ GaAs of thickness at or about 0.05 μm with an n+ doping concentration level at or about 7e18 cm⁻³.

13. The triple junction solar cell of claim 1 wherein said first tunnel junction layer comprises:
a first tunnel base layer of n+ GaAs of thickness at or about 0.015 μm with an n+ doping concentration level at or about 1e19 cm⁻³; and
a first tunnel emitter layer of p+ GaAs of thickness at or about 0.015 μm with a p+ doping concentration level at or about 8e18 cm⁻³.

14. The triple junction solar cell of claim 1 wherein said middle GaAs layer comprises:
a first buffer layer of p+ GaAs of thickness at or about 0.3 μm with a p+ doping concentration level at or about 7e18 cm⁻³;
a first BSF layer of p+ InGaP of thickness at or about 0.01 μm with a p+ doping concentration level at or about 5e19 cm⁻³;
a first base layer of p+ GaAs of thickness at or about 3.87 μm with a p+ doping concentration level at or about 1e17 cm⁻³;
a second emitter layer of n+ GaAs of thickness at or about 0.01 μm with an n+ doping concentration level at or about 4.64e15 cm⁻³; and
a second window layer of n+ AlInP of thickness at or about 0.01 μm with an n+ doping concentration level at or about 4.64e17 cm⁻³.

15. The triple junction solar cell of claim 1 wherein said second tunnel junction layer comprises:
a second tunnel base layer of n+ InGaP of thickness at or about 0.015 μm with an n+ doping concentration level at or about 1e19 cm⁻³; and
a second tunnel emitter layer of p+ InGaP of thickness at or about 0.015 μm with a p+ doping concentration level at or about 8e18 cm⁻³.

16. The triple junction solar cell of claim 1 wherein said top InGaP layer comprises:
a second buffer layer of p+ AlInP of thickness at or about 0.03 μm with a p+ doping concentration level at or about 1e18 cm⁻³;
a second BSF layer of p+ InGaP of thickness at or about 0.01 μm with a p+ doping concentration level at or about 5e19 cm⁻³;
a second base layer of p+ InGaP of thickness at or about 0.63 μm with a p+ doping concentration level at or about 1e17 cm⁻³;
a third emitter layer of n+ InGaP of thickness at or about 0.17 μm with an n+ doping concentration level at or about 4.64e17 cm⁻³; and
a third window layer of n+ AlInP of thickness at or about 0.01 μm with an n+ doping concentration level at or about 5e19 cm⁻³.

17. A triple junction solar cell comprising:
a bottom Ge layer comprising:
a substrate layer of doped p+ Ge of thickness at or about 300 μm with a p+ doping concentration level at or about 3e18 cm⁻³;
a first emitter layer of n+ Ge of thickness at or about 0.1 μm with an n+ doping concentration level at or about 3e18 cm⁻³; and
a first window layer of n+ GaAs of thickness at or about 0.05 μm with an n+ doping concentration level at or about 7e18 cm⁻³;
a first tunnel junction layer in contact with said bottom Ge layer comprising:
a first tunnel base layer of n+ GaAs of thickness at or about 0.015 μm with an n+ doping concentration level at or about 1e19 cm⁻³; and
a first tunnel emitter layer of p+ GaAs of thickness at or about 0.015 μm with a p+ doping concentration level at or about 8e18 cm⁻³;
middle GaAs layer in contact with said first tunnel junction layer comprising:
a first buffer layer of p+ GaAs of thickness at or about 0.3 μm with a p+ doping concentration level at or about 7e18 cm⁻³;
a first BSF layer of p+ InGaP of thickness at or about 0.01 μm with a p+ doping concentration level of 5e19 cm⁻³;
a first base layer of p+ GaAs of thickness at or about 3.87 μm with a p+ doping concentration level at or about 1e17 cm⁻³;
a second emitter layer of n+ GaAs of thickness at or about 0.01 μm with an n+ doping concentration level at or about 4.64e15 cm⁻³; and
a second window layer of n+ AlInP of thickness at or about 0.01 μm with an n+ doping concentration level at or about 4.64e17 cm⁻³;
a second tunnel junction layer in contact with said middle GaAs layer comprising:
a second tunnel base layer of n+ InGaP of thickness at or about 0.015 μm with an n+ doping concentration level at or about 1e19 cm⁻³; and
a second tunnel emitter layer of p+ InGaP of thickness at or about 0.015 μm with a p+ doping concentration level at or about 8e18 cm⁻³; and
a top InGaP layer in contact with said second tunnel junction layer comprising:
a second buffer layer of p+ AlInP of thickness at or about 0.03 μm with a p+ doping concentration level at or about 1e18 cm⁻³;
a second BSF layer of p+ InGaP of thickness at or about 0.01 μm with a p+ doping concentration level at or about 5e19 cm⁻³;
a second base layer of p+ InGaP of thickness at or about 0.63 μm with a p+ doping concentration level at or about 1e17 cm⁻³;
a third emitter layer of n+ InGaP of thickness at or about 0.17 μm with an n+ doping concentration level at or about 4.64e17 cm⁻³; and
a third window layer of n+ AlInP of thickness at or about 0.01 μm with an n+ doping concentration level at or about 5e19 cm⁻³.

18. The triple junction solar cell of claim 17 further comprising:
one or more electrically conductive contacts for transferring energy produced by said triple junction solar cell to another device.

19. A method for forming a triple junction solar cell comprising:
forming a bottom Ge layer, wherein forming said bottom Ge layer comprises:
forming a substrate layer of doped p+ Ge of thickness at or about 300 μm with a p+ doping concentration level at or about 3e18 cm⁻³;
forming a first emitter layer of n+ Ge of thickness at or about 0.1 μm with an n+ doping concentration level at or about 3e18 cm⁻³; and
forming a first window layer of n+ GaAs of thickness at or about 0.05 μm with an n+ doping concentration level at or about 7e18 cm⁻³;
a first tunnel junction layer in contact with said bottom Ge layer comprising:
forming a first tunnel base layer of n+ GaAs of thickness at or about 0.015 μm with an n+ doping concentration level at or about 1e19 cm⁻³; and
forming a first tunnel emitter layer of p+ GaAs of thickness at or about 0.015 μm with a p+ doping concentration level at or about 8e18 cm⁻³;
forming a middle GaAs layer in contact with said first tunnel junction layer comprising:
forming a first buffer layer of p+ GaAs of thickness at or about 0.3 μm with a p+ doping concentration level at or about 7e18 cm⁻³;
forming a first BSF layer of p+ InGaP of thickness at or about 0.01 μm with a p+ doping concentration level at or about 5e19 cm⁻³;
forming a first base layer of p+ GaAs of thickness at or about 3.87 μm with a p+ doping concentration level at or about 1e17 cm⁻³;
forming a second emitter layer of n+ GaAs of thickness at or about 0.01 μm with an n+ doping concentration level at or about 4.64e15 cm⁻³; and
forming a second window layer of n+ AlInP of thickness at or about 0.01 μm with an n+ doping concentration level at or about 4.64e17 cm⁻³;
forming a second tunnel junction layer in contact with said middle GaAs layer comprising:
forming a second tunnel base layer of n+ InGaP of thickness at or about 0.015 μm with an n+ doping concentration level at or about 1e19 cm⁻³; and
forming a second tunnel emitter layer of p+ InGaP of thickness at or about 0.015 μm with a p+ doping concentration level at or about 8e18 cm⁻³; and
forming a top InGaP layer in contact with said second tunnel junction layer comprising:
forming a second buffer layer of p+ AlInP of thickness at or about 0.03 μm with a p+ doping concentration level at or about 1e18 cm⁻³;
forming a second BSF layer of p+ InGaP of thickness at or about 0.01 μm with a p+ doping concentration level at or about 5e19 cm⁻³;
forming a second base layer of p+ InGaP of thickness at or about 0.63 μm with a p+ doping concentration level at or about 1e17 cm⁻³;
forming a third emitter layer of n+ InGaP of thickness at or about 0.17 μm with an n+ doping concentration level at or about 4.64e17 cm⁻³; and
forming a third window layer of n+ AlInP of thickness at or about 0.01 μm with an n+ doping concentration level at or about 5e19 cm⁻³.

20. The method of claim 19 further comprising:
attaching one or more electrically conductive contacts to said triple junction solar cell for transferring energy produced by said triple junction solar cell to another device.
